(19) United States
(12) Patent Application Publication
(10) Pub. No.: US 2019/0334509 A1
(43) Pub. Date: Oct. 31, 2019

(54) SELF-COMPENSATED OSCILLATOR CIRCUIT

(71) Applicant: STMicroelectronics International N.V., Schiphol (NL)

(72) Inventors: Nitin GUPTA, Kurukshetra (IN); Nitin JAIN, Ghaziabad (IN)

(73) Assignee: STMicroelectronics International N.V., Schiphol (NL)

(21) Appl. No.: 15/962,089

(22) Filed: Apr. 25, 2018

(51) Int. Cl. H03K 3/354; H03L 5/00

(52) U.S. Cl. CPC H03K 3/3545; H03L 5/00

(57) ABSTRACT

A ring oscillator circuit is formed by series connected inverter circuits with a feedback loop. The inverter circuits are source biased with an oscillator voltage. A resistor-less bias current generator circuit generates a bias current for application to a replica inverter circuit to generate a bias voltage. A scaling circuit operates to scale the bias voltage by a selectable scaling factor to generate the oscillator voltage in a manner which balances a mobility effect of the inverter circuits within the ring oscillator circuit against a threshold voltage effect of the inverter circuits within the ring oscillator circuit. The clock signal output from the ring oscillator circuit has a frequency which is independent of process, voltage and temperature (PVT) spread.

### TECHNICAL FIELD

The present invention relates to an oscillator circuit and, in particular, to an oscillator circuit with process, voltage and temperature (PVT) compensation.

### BACKGROUND

It is common for an integrated circuit chip to include an on-chip oscillator. One commonly used oscillator circuit is a resistor-capacitor (RC) oscillator which exhibits a raw spread across process, voltage and temperature (PVT) on the order of 70% peak-to-peak (primarily due to resistance spread and capacitance spread). To trim for the process variation, a digital-to-analog converter (DAC) circuit is used, but the requirements for the DAC in this application are unfortunately quite large. For instance, to achieve a 0.2% trimmed accuracy, a nine or ten bit DAC is needed. Such a DAC circuit occupies a large amount of chip real estate and the circuit is also very complex. Additionally, this solution only addresses process variation, and the temperature variation of the RC oscillator is still present and compensation for this is known to be difficult. Additional oscillator-related circuits, such as the use of comparator circuits, further contribute to uncompensated, or incompletely compensated, temperature variation, and may further introduce phase noise.

There is accordingly a need in the art for an on-chip oscillator circuit which supports PVT compensation. Ideally, the oscillator would exhibit minimal spread across process and voltage and less spread across temperature while also possessing good phase noise characteristics.

### SUMMARY

In an embodiment, a circuit comprises: a ring oscillator circuit comprising a plurality of inverter circuits connected in series with a feedback loop, said plurality of inverter circuits being source biased with an oscillator voltage; a resistor-less bias current generator circuit configured to generate a bias current; a replica inverter circuit that is source biased with the bias current to generate a bias voltage; and a scaling circuit configured to scale the bias voltage by a scaling factor to generate the oscillator voltage.

In an embodiment, a circuit comprises: a ring oscillator circuit comprising a plurality of inverter circuits connected in series with a feedback loop, said plurality of inverter circuits being source biased with a bias current; and a resistor-less bias current generator circuit configured to generate the bias current.

In an embodiment, a circuit comprises: a ring oscillator circuit comprising a plurality of inverter circuits connected in series with a feedback loop, said plurality of inverter circuits being source biased with an oscillator voltage; a bias current generator circuit configured to generate a bias current; a replica inverter circuit that is source biased with the bias current to generate a bias voltage; and a scaling circuit configured to scale the bias voltage by a scaling factor to generate the oscillator voltage.

### BRIEF DESCRIPTION OF THE DRAWINGS

For a better understanding of the embodiments, reference will now be made by way of example only to the accompanying figures in which:

FIG. 1 is a circuit diagram of a self-compensated oscillator circuit; and

FIG. 2 is a circuit diagram of a self-compensated oscillator circuit.

### DETAILED DESCRIPTION

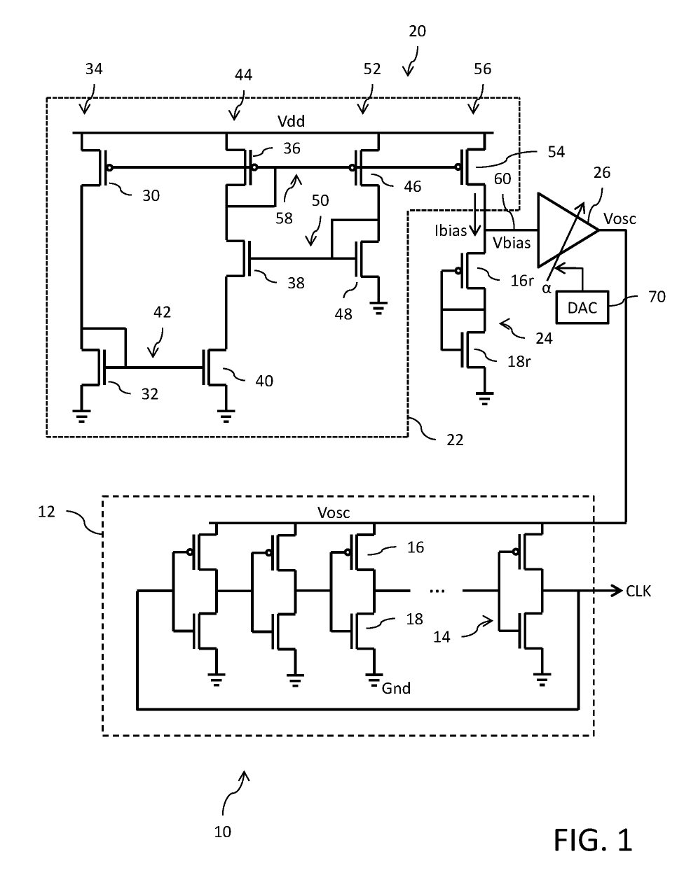

Reference is now made to FIG. 1 which shows a circuit diagram of a self-compensated oscillator circuit 10. The output clock signal CLK is generated by a ring oscillator circuit 12 biased by a voltage Vosc. The ring oscillator circuit 12 is formed by an odd number of series connected logic inverters 14, wherein an output of a last one of the inverters is connected to an input of a first one of the inverters in a feedback loop. The logic inverters 14 comprise CMOS logic inverters formed by a p-channel MOSFET device 16 and an n-channel MOSFET device 18 that have their source-drain paths connected in series, with the common gate terminals of the two devices forming the inverter input and the common drain terminals of the two devices forming the inverter output. The source terminals of the p-channel MOSFET devices in the ring oscillator circuit 12 are biased by the voltage Vosc and the source terminals of the n-channel MOSFET devices in the ring oscillator circuit 12 are tied to a reference supply voltage node (for example, ground). The frequency of the output clock signal CLK is dependent on the voltage Vosc, and there is a need in most circuits for this frequency to be substantially constant across process, voltage and temperature (PVT).

A voltage generator circuit 20 provides the voltage Vosc for biasing the ring oscillator circuit 12. The voltage generator circuit 20 includes a current generator circuit 22 configured to generate a bias current Ibias, a replica ring inverter circuit 24 that is biased by the bias current Ibias to generate a bias voltage Vbias, and a voltage scaling circuit 26 configured to receive the bias voltage Vbias and output the voltage Vosc, where Vosc=α*Vbias, and where α is a selectable scaling factor.

The current generator circuit 22 includes a p-channel MOSFET device 30 having a source terminal connected to a positive supply voltage Vdd node. The drain terminal of the p-channel MOSFET device 30 is connected to the drain terminal of an n-channel MOSFET device 32 that is configured as a diode-connected transistor with its drain terminal connected to its gate terminal. The MOSFET devices 30 and 32 have their source-drain paths connected in series between the positive supply voltage Vdd node and the reference supply voltage node (for example, ground) to form a first circuit leg 34 of the current generator circuit 22.

A p-channel MOSFET device 36 has a source terminal connected to the positive supply voltage Vdd node and is configured as a diode-connected transistor with its drain terminal connected to its gate terminal. The drain terminal of the p-channel MOSFET device 36 is connected to the drain terminal of an n-channel MOSFET device 38. The source terminal of the n-channel MOSFET device 38 is connected to the drain terminal of an n-channel MOSFET device 40. A gate terminal of the n-channel MOSFET device 40 is connected to the gate terminal of the n-channel MOSFET device 32 to form a current mirror circuit 42. The MOSFET devices 36, 38 and 40 have their source-drain paths connected in series between the positive supply voltage Vdd node and the reference supply voltage node to form a second circuit leg 44 of the current generator circuit 22.

A p-channel MOSFET device 46 has a source terminal connected to the positive supply voltage Vdd node. The drain terminal of the p-channel MOSFET device 46 is connected to the drain terminal of an n-channel MOSFET device 48 that is configured as a diode-connected transistor with its drain terminal connected to its gate terminal. A gate terminal of the n-channel MOSFET device 48 is connected to the gate terminal of the n-channel MOSFET device 38 to form a sub-threshold circuit 50 (i.e., a circuit where the n-channel devices 38 and 48 operate in the sub-threshold region). The MOSFET devices 46 and 48 have their source-drain paths connected in series between the positive supply voltage Vdd node and the reference supply voltage node to form a third circuit leg 52 of the current generator circuit 22.

A p-channel MOSFET device 54 has a source terminal connected to a positive supply voltage Vdd node and a drain terminal which generates the bias current Ibias. The MOSFET device 54 forms a fourth circuit leg 56 of the current generator circuit 22.

The gate terminals of the MOSFET devices 30, 36, 36 and 54 are connected together to form a current mirror circuit 58.

The bias current Ibias generated at the drain of channel MOSFET device 54 is given by the following equation:

$$Ibias = 2 \frac{{β}_{40}^{2}}{{β}_{32}} {{V}_{T}^{2} ( ln ( \frac{{β}_{38}}{{β}_{48}} ) )}^{2} Iout = 2 \frac{{β}_{40}^{2}}{{β}_{32}} {{V}_{T}^{2} ( ln ( \frac{{β}_{38}}{{β}_{48}} ) )}^{2}$$

Where: β₃₂, β₃₈, β₄₀ and β₄₈ are the beta values for the transistors 32, 38, 40 and 48, respectively, and V_{T} is the thermal voltage (KT/q).

The bias current Ibias is a process and temperature dependent current that exhibits approximately a square root of a proportional to absolute temperature (PTAT) response. The current is process dependent because there is mobility factor which has some process dependence. Importantly, the current generator circuit 22 does not utilize a physical resistor in the circuitry which helps to minimize concerns with resistor spread. In a preferred implementation, the MOSFET devices used within the resistor-less current generator circuit 22 are all of a low threshold voltage type with thin gate oxides designed for operation at low supply voltage levels. These devices are commonly known in the art as GO1 type devices. In any case, the devices have thin gate oxides, and those thin gate oxides may be same or similar to the gate oxides used by devices in ring oscillator circuit.

The current generator circuit 22 represents just one example of a suitable resistor-less current generator circuit. In operation, the n-channel transistors 38 and 48 operate in the sub-threshold region and the p-channel transistors operate in saturation. The n-channel transistor 40 is effectively a resistance (which is controlled by its gate-to-source voltage, which is in turn set by n-channel transistor 42). The n-channel transistor 42 operates in saturation. The current is generated using a resistor-less circuit and has a square root of PTAT characteristic.

The replica ring inverter circuit 24 is formed by a p-channel MOSFET device 16r and an n-channel MOSFET device 18r that have their source-drain paths connected in series between node 60 and the reference supply voltage node in circuit leg 56. The devices 16r and 18r share a common drain terminal, and the gate terminals of the devices 16r and 18r are connected to the common drain terminal, thus configuring both devices 16r and 18r as diode-connected transistors. The p-channel MOSFET device 16r is a replica of the p-channel MOSFET device 16 that is used within the within the ring oscillator circuit 12. Likewise, the n-channel MOSFET device 18r is a replica of the n-channel MOSFET device 18 that is used within the within the ring oscillator circuit 12. In this context, replica means that the transistors are copies of each other and thus share the same dimensions and characteristics (width, length, gate oxide thickness, dopant concentrations, etc). In an implementation, a device is considered a replica of another device if the two devices have scaled versions of width/length, but there is no requirement for an exact size replication. Matching of size relative the limitations of the fabrication process technology node used to make the transistor devices is sufficient to meet the requirement for replication.

The bias current Ibias that is applied to pass through and forward bias the two diode-connected replica transistors 16r and 18r that are connected in series with each other will cause a bias voltage Vbias to be generated at node 60. Because of the use of replica devices, this bias voltage Vbias is dependent on the mobility and threshold voltage of the inverter 14 used within the ring oscillator circuit 12.

The voltage scaling circuit 26 is formed by a differential amplifier circuit having an adjustable gain that sets a selectable scaling factor α such that the output voltage Vosc generated by the voltage scaling circuit 26 is scaled relative to the input voltage Vbias in accordance with the following: Vosc=α*Vbias. The gain which sets the selectable scaling factor α is a trimmable value controlled by the output of a digital-to-analog converter (DAC) circuit 70. In an alternative embodiment, the circuit 26 may be configured in a unity gain buffer configuration.

The scaling factor α is typically less than 1. For example, a scaling factor α in the range of 0.57 to 0.60 is typical and would serve to effectively compensate for temperature variation on output clock frequency.

With an increase in temperature, the threshold voltage of the transistors decreases and mobility increases. At relatively higher supply voltages for the ring oscillator circuit 12, the mobility aspect is dominant; while at relatively lower supply voltages for the ring oscillator circuit 12, the threshold voltage is dominant. The scaling factor α accounts for those relationships. There is a range of voltage for the ring oscillator circuit 12 supply voltage Vosc where the foregoing two effects compensate and offset. The selection of the scaling factor α helps to achieve a minimum spread across temperature range. As a result, the circuit 10 achieves a raw oscillator frequency spread of 20-25% peak-to-peak, and as a result this considerably reduces the circuit requirement for the trimming DAC. In an embodiment, a seven bit DAC is sufficient for implementing the trimming to achieve a 0.2% trimmed accuracy. Also, temperature spread across process is within 10% peak-to-peak.

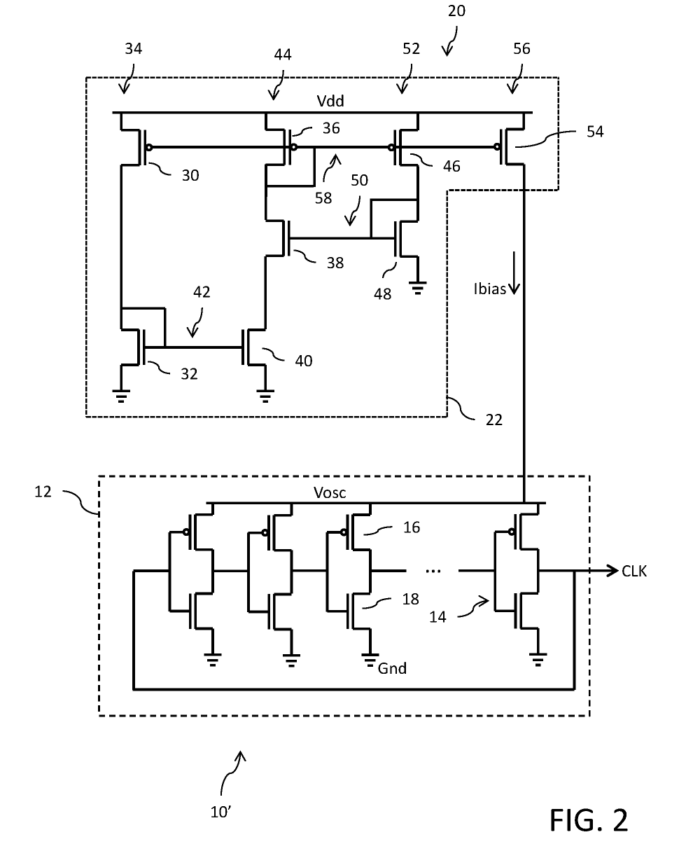

FIG. 2 shows an alternative implementation where the bias current Ibias in circuit leg 56 is instead applied directly to the source terminals of the p-channel MOSFET devices of the inverters 14 within the ring oscillator circuit 12. The purpose here is to provide a low power implementation. The replica is not used. In this case, the main design consideration is to set the voltage Vosc of the ring oscillator such that the oscillation frequency is constant across PVT. As noted, there is a trade-off between mobility and threshold voltage variation with temperature while choosing the voltage Vosc of the ring oscillator.

Because the implementation of FIG. 2 lacks the replica ring inverter circuit 24 and the voltage scaling circuit 26, more attention must be directed to the design of the ring oscillator circuit 12 to provide for self-compensation.

While the invention has been illustrated and described in detail in the drawings and foregoing description, such illustration and description are considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims.

What is claimed is:

1. A circuit, comprising:
a ring oscillator circuit comprising a plurality of inverter circuits connected in series with a feedback loop, said plurality of inverter circuits being source biased with an oscillator voltage;
a resistor-less bias current generator circuit configured to generate a bias current;
a replica inverter circuit that is source biased with the bias current to generate a bias voltage; and
a scaling circuit configured to scale the bias voltage by a scaling factor to generate the oscillator voltage.

2. The circuit of claim 1, wherein the resistor-less bias current generator circuit comprises:
a first p-channel MOSFET;
a second p-channel MOSFET in a diode-connected configuration;
a third p-channel MOSFET;
a fourth p-channel MOSFET having a drain generating the bias current;
wherein the first through fourth p-channel MOSFETs form a current mirror circuit;
a first n-channel MOSFET in a diode-connected configuration that is connected in series with the first p-channel MOSFET;
a second n-channel MOSFET in a diode-connected configuration that is connected in series with the third p-channel MOSFET;
a third n-channel MOSFET coupled in series with the second p-channel MOSFET, wherein gates of the second and third n-channel MOSFET are connected to each other; and
a fourth n-channel MOSFET coupled in series with the third n-channel MOSFET, wherein the first and fourth n-channel MOSFETs form a further current mirror circuit.

3. The circuit of claim 1, wherein the scaling circuit comprises a differential amplifier circuit with an adjustable gate that sets the scaling factor.

4. The circuit of claim 3, further comprising a digital-to-analog converter circuit configured to select the adjustable gain.

5. The circuit of claim 1, wherein the resistor-less bias current generator circuit consists of:
a first p-channel MOSFET;
a second p-channel MOSFET in a diode-connected configuration;
a third p-channel MOSFET;
a fourth p-channel MOSFET having a drain generating the bias current;
wherein the first through fourth p-channel MOSFETs form a current mirror circuit;
a first n-channel MOSFET in a diode-connected configuration that is connected in series with the first p-channel MOSFET;
a second n-channel MOSFET in a diode-connected configuration that is connected in series with the third p-channel MOSFET;
a third n-channel MOSFET coupled in series with the second p-channel MOSFET, wherein gates of the second and third n-channel MOSFET are connected to each other; and
a fourth n-channel MOSFET coupled in series with the third n-channel MOSFET, wherein the first and fourth n-channel MOSFETs form a further current mirror circuit.

6. The circuit of claim 1, wherein the bias current has a square root of proportional to absolute temperature (PTAT) characteristic.

7. The circuit of claim 1, wherein the scaling factor has a value which balances a mobility effect of the inverter circuits within the ring oscillator circuit against a threshold voltage effect of the inverter circuits within the ring oscillator circuit so that a clock signal output from the ring oscillator circuit has a frequency which is independent of process, voltage and temperature (PVT) spread.

8. A circuit, comprising:
a ring oscillator circuit comprising a plurality of inverter circuits connected in series with a feedback loop, said plurality of inverter circuits being source biased with a bias current; and
a resistor-less bias current generator circuit configured to generate the bias current.

9. The circuit of claim 8, wherein the resistor-less bias current generator circuit comprises:
a first p-channel MOSFET;
a second p-channel MOSFET in a diode-connected configuration;
a third p-channel MOSFET;
a fourth p-channel MOSFET having a drain generating the bias current;
wherein the first through fourth p-channel MOSFETs form a current mirror circuit;
a first n-channel MOSFET in a diode-connected configuration that is connected in series with the first p-channel MOSFET;
a second n-channel MOSFET in a diode-connected configuration that is connected in series with the third p-channel MOSFET;
a third n-channel MOSFET coupled in series with the second p-channel MOSFET, wherein gates of the second and third n-channel MOSFET are connected to each other; and
a fourth n-channel MOSFET coupled in series with the third n-channel MOSFET, wherein the first and fourth n-channel MOSFETs form a further current mirror circuit.

10. The circuit of claim 8, wherein the resistor-less bias current generator circuit consists of:
a first p-channel MOSFET;
a second p-channel MOSFET in a diode-connected configuration;
a third p-channel MOSFET;
a fourth p-channel MOSFET having a drain generating the bias current;
wherein the first through fourth p-channel MOSFETs form a current mirror circuit;
a first n-channel MOSFET in a diode-connected configuration that is connected in series with the first p-channel MOSFET;
a second n-channel MOSFET in a diode-connected configuration that is connected in series with the third p-channel MOSFET;
a third n-channel MOSFET coupled in series with the second p-channel MOSFET, wherein gates of the second and third n-channel MOSFET are connected to each other; and
a fourth n-channel MOSFET coupled in series with the third n-channel MOSFET, wherein the first and fourth n-channel MOSFETs form a further current mirror circuit.

11. The circuit of claim 7, wherein the bias current has a square root of proportional to absolute temperature (PTAT) characteristic.

12. A circuit, comprising:
a ring oscillator circuit comprising a plurality of inverter circuits connected in series with a feedback loop, said plurality of inverter circuits being source biased with an oscillator voltage;
a bias current generator circuit configured to generate a bias current;
a replica inverter circuit that is source biased with the bias current to generate a bias voltage; and
a scaling circuit configured to scale the bias voltage by a scaling factor to generate the oscillator voltage.

13. The circuit of claim 12, wherein the bias current generator circuit is a resistor-less circuit.

14. The circuit of claim 13, wherein the bias current generator circuit comprises:
a first p-channel MOSFET;
a second p-channel MOSFET in a diode-connected configuration;
a third p-channel MOSFET;
a fourth p-channel MOSFET having a drain generating the bias current;
wherein the first through fourth p-channel MOSFETs form a current mirror circuit;
a first n-channel MOSFET in a diode-connected configuration that is connected in series with the first p-channel MOSFET;
a second n-channel MOSFET in a diode-connected configuration that is connected in series with the third p-channel MOSFET;
a third n-channel MOSFET coupled in series with the second p-channel MOSFET, wherein gates of the second and third n-channel MOSFET are connected to each other; and
a fourth n-channel MOSFET coupled in series with the third n-channel MOSFET, wherein the first and fourth n-channel MOSFETs form a further current mirror circuit.

15. The circuit of claim 13, wherein the scaling circuit comprises a differential amplifier circuit with an adjustable gain that sets the scaling factor.

16. The circuit of claim 15, further comprising a digital-to-analog converter circuit configured to select the adjustable gain.

17. The circuit of claim 12, wherein the bias current has a square root of proportional to absolute temperature (PTAT) characteristic.

18. The circuit of claim 12, wherein the scaling factor has a value which balances a mobility effect of the inverter circuits within the ring oscillator circuit against a threshold voltage effect of the inverter circuits within the ring oscillator circuit so that a clock signal output from the ring oscillator circuit has a frequency which is independent of process, voltage and temperature (PVT) spread.
